(19) United States
(12) Patent Application Publication
(10) Pub. No.: US 2026/0341378 A1
(43) Pub. Date: Oct. 29, 2026

(54) NON-VOLATILE MEMORY DEVICE AND OPERATING METHOD THEREOF

(71) Applicant: SK hynix Inc., Gyeonggi-do (KR)

(72) Inventors: Sagar Rajendrabhai Upadhyay, San Jose, CA (US); Bhavya Lokasani, San Jose, CA (US); Harichandana Chitturi, San Jose, CA (US)

(21) Appl. No.: 19/187,857

(22) Filed: Apr. 23, 2025

(51) Int. Cl. G11C 16/34; G11C 16/30

(52) U.S. Cl. CPC G11C 16/3454; G11C 16/30

(57) ABSTRACT

An operating method of a non-volatile memory device includes concurrently performing multiple program operations on planes of memory cells each configured to store data of plural bits. Each of the multiple program operations includes plural program loops each including a pulse application step and one or more verification steps including a predictive-CSC-verification according to a predictive current sense comparison (CSC) scheme. The multiple program operations are performed while skipping, when a first plane among the planes passes the predictive-CSC-verification for a program-target level in an M^{th} program loop, precharge of bit lines in the first plane during the verification steps on the first plane for the program-target level in remaining program loops.

### BACKGROUND

### 1.Field

Embodiments of the present disclosure relate to a memory system and an operating method thereof.

A memory system stores data in response to a request from a host system such as a computer, smartphone, or smart pad. An example of a memory system is a system configured to store data in a semiconductor memory, especially in a nonvolatile memory, such as a solid-state drive (SSD) or a memory card.

A memory system includes a memory device configured to store data and a controller configured to control the memory device. Generally, a memory device may be volatile or nonvolatile. Examples of a nonvolatile memory device are Read Only Memory (ROM), Programmable ROM (PROM), Electrically Programmable ROM (EPROM), Electrically Erasable and Programmable ROM (EEPROM), flash memory, Phase-change RAM (PRAM), Magnetic RAM (MRAM), Resistive RAM (RRAM), and Ferroelectric RAM (FRAM).

### SUMMARY

In an embodiment of the present disclosure, an operating method of a non-volatile memory device, having plural planes of memory cells each configured to store data of plural bits, may include concurrently performing multiple program operations on planes selected from among the plural planes. Each of the multiple program operations may include plural program loops each including a pulse application step and one or more verification steps including a predictive-CSC-verification according to a predictive current sense comparison (CSC) scheme. The multiple program operations may be performed while skipping, in response to a determination that a first plane among the selected planes passes the predictive-CSC-verification for a program-target level in an M^{th} program loop among the plural program loops, precharge of bit lines in the first plane during the verification steps on the first plane for the program-target level in remaining program loops after the M^{th} program loop, among the plural program loops.

The multiple program operations may be performed further by skipping, in response to a determination that a second plane among the selected planes passes the predictive-CSC-verification for a last program-target level in an L^{th} program loop among the plural program loops, biasing of bit lines and word lines in the second plane during the pulse application steps and verification steps on the second plane for the last program-target level in remaining program loops after the L^{th} program loop, among the plural program loops.

The predictive-CSC-verification may be performed on a corresponding plane of the selected planes for a program-target level by: determining that the corresponding plane passes the predictive-CSC-verification for the program-target level in response to a number of fail-bits for the program-target level, which is less than a threshold and acquired from information of previous program loops among the plural program loops; and stopping subsequent verification steps on the corresponding plane for the program-target level while program-inhibiting the corresponding plane in subsequent pulse application steps within the plural program loops.

In an embodiment of the present disclosure, an operating method of a non-volatile memory device, having plural planes of memory cells each configured to store data of plural bits, may include concurrently performing multiple program operations on planes selected from among the plural planes. Each of the multiple program operations may include plural program loops each including a pulse application step and one or more verification steps including a predictive-CSC-verification according to a predictive current sense comparison (CSC) scheme. The multiple program operations may be performed while skipping, in response to a determination that a first plane among the selected planes passes the predictive-CSC-verification for a last program-target level in an L^{th} program loop among the plural program loops, biasing of bit lines and word lines in the first plane during the pulse application steps and verification steps on the first plane for the last program-target level in remaining program loops after the L^{th} program loop, among the plural program loops.

The multiple program operations may be performed further while skipping, in response to a determination that a second plane among the selected planes passes the predictive-CSC-verification for a program-target level in an M^{th} program loop among the plural program loops, precharge of bit lines in the first plane during the verification steps on the second plane for the program-target level in remaining program loops after the M^{th} program loop, among the plural program loops.

The predictive-CSC-verification may be performed on a corresponding plane of the selected planes for a program-target level by: determining that the corresponding plane passes the predictive-CSC-verification for the program-target level in response to a number of fail-bits for the program-target level, which is less than a threshold, and acquired from information of previous program loops among the plural program loops; and stopping subsequent verification steps on the corresponding plane for the program-target level while program-inhibiting the corresponding plane in the subsequent pulse application steps within the plural program loops.

In an embodiment of the present disclosure, a non-volatile memory device may include plural planes of memory cells and a peripheral circuit. Each memory cell may be configured to store data of plural bits. The peripheral circuit may be configured to concurrently perform multiple program operations on planes selected among the plural planes. Each of the multiple program operations may include plural program loops each including a pulse application step and one or more verification steps including a predictive-CSC-verification according to a predictive current sense comparison (CSC) scheme. The peripheral circuit may concurrently perform the multiple program operations by skipping, when a first plane among the selected planes passes the predictive-CSC-verification for a program-target level in an M^{th} program loop among the plural program loops, precharge of bit lines in the first plane during the verification steps on the first plane for the program-target level in remaining program loops after the M^{th} program loop, among the plural program loops.

The peripheral circuit may concurrently perform the multiple program operations further by skipping, when a second plane among the selected planes passes the predictive-CSC-verification for a last program-target level in an L^{th} program loop among the plural program loops, biasing of bit lines and word lines in the second plane during the pulse application steps and verification steps on the second plane for the last program-target level in remaining program loops after the L^{th} program loop, among the plural program loops.

The peripheral circuit may perform the predictive-CSC-verification on a corresponding plane of the selected planes for a program-target level by: determining that the corresponding plane passes the predictive-CSC-verification for the program-target level when a number of fail-bits for the program-target level, which is acquired from information of previous program loops among the plural program loops, is less than a threshold; and stopping subsequent verification steps on the corresponding plane for the program-target level while program-inhibiting the corresponding plane in the subsequent pulse application steps within the plural program loops.

In an embodiment of the present disclosure, a non-volatile memory device may include plural planes of memory cells and a peripheral circuit. Each memory cell may be configured to store data of plural bits. The peripheral circuit may be configured to concurrently perform multiple program operations on planes selected from among the plural planes. Each of the multiple program operations may include plural program loops each including a pulse application step and one or more verification steps including a predictive-CSC-verification according to a predictive current sense comparison (CSC) scheme. The peripheral circuit may concurrently perform the multiple program operations by skipping, when a first plane among the selected planes passes the predictive-CSC-verification for a last program-target level in an L^{th} program loop among the plural program loops, biasing of bit lines and word lines in the first plane during the pulse application steps and verification steps on the first plane for the last program-target level in remaining program loops after the L^{th} program loop, among the plural program loops.

The peripheral circuit may concurrently perform the multiple program operations further by skipping, when a second plane among the selected planes passes the predictive-CSC-verification for a program-target level in an M^{th} program loop among the plural program loops, precharge of bit lines in the first plane during the verification steps on the second plane for the program-target level in remaining program loops after the M^{th} program loop, among the plural program loops.

The peripheral circuit may perform the predictive-CSC-verification on a corresponding plane of the selected planes for a program-target level by: determining that the corresponding plane passes the predictive-CSC-verification for the program-target level when a number of fail-bits for the program-target level, which is acquired from information of previous program loops among the plural program loops, is less than a threshold; and stopping subsequent verification steps on the corresponding plane for the program-target level while program-inhibiting the corresponding plane in the subsequent pulse application steps within the plural program loops.

Additional embodiments of the present disclosure will become apparent from the following description.

### BRIEF DESCRIPTION OF THE DRAWINGS

FIG. 1 illustrates a memory system.

FIG. 2 illustrates a data processing system.

FIG. 3 illustrates a controller.

FIG. 4 illustrates a memory device.

FIGS. 5 and 6 illustrate a program operation on TLCs according to an embodiment of the present disclosure.

FIG. 7 illustrates voltages applied to a word line and bit lines during a program operation on TLCs.

FIG. 8 schematically illustrates pages included in a memory block.

FIG. 9 schematically illustrates a program operation of a predictive CSC scheme according to an embodiment of the present disclosure.

FIG. 10 illustrates multi-plane QLC program operations according to an embodiment of the present disclosure.

FIG. 11 illustrates multi-plane program operations of programming pages of memory cells within multi-planes to a program-target level with respect to FIG. 10.

FIG. 12 illustrates multi-plane program operations of programming pages of memory cells within multi-planes to the last program-target level with respect to FIG. 10.

FIG. 13 illustrates a page buffer circuit configured to bias a bit line of a memory group illustrated in FIG. 4 .

### DETAILED DESCRIPTION

Various embodiments of the present disclosure are described below in more detail with reference to the accompanying drawings. The present invention may, however, be embodied in different forms and thus should not be construed as limited to the embodiments set forth herein. Rather, these embodiments are provided so that this disclosure conveys the scope of the present invention to those skilled in the art. Moreover, references herein to “an embodiment,” “another embodiment,” or the like is not necessarily to only one embodiment, and different references to any such phrase are not necessarily to the same embodiment(s). The term “embodiments” as used herein does not necessarily refer to all embodiments. Throughout this disclosure, like reference numerals refer to like parts in the figures and embodiments of the present disclosure.

Embodiments of the present disclosure may be implemented in numerous ways, including as a process; an apparatus; a system; a computer program product embodied on a computer-readable storage medium; and/or a processor, such as a processor suitable for executing instructions stored on and/or provided by a memory coupled to the processor. In this specification, these embodiments, or any other form that the present invention may take, may be referred to as techniques. In general, the order of the operations of disclosed processes may be altered within the scope of the present disclosure. Unless stated otherwise, a component such as a processor or a memory described as being suitable for performing a task may be implemented as a general device or circuit component that is configured or otherwise programmed to perform the task at a given time or as a specific device or circuit component that is manufactured to perform the task. As used herein, the term ‘processor’ or the like refers to one or more devices, circuits, and/or processing cores suitable for processing data, such as computer program instructions.

The methods, processes, and/or operations described herein may be performed by code or instructions to be executed by a computer, processor, controller, or other signal processing device. The computer, processor, controller, or other signal processing device may be those described herein or one in addition to the elements described herein. Because the algorithms that form the basis of the methods (or operations of the computer, processor, controller, or other signal processing device) are described herein, the code or instructions for implementing the operations of the method embodiments may transform the computer, processor, controller, or other signal processing device into a special-purpose processor for performing methods herein.

As used in this disclosure, the term “circuitry” or “logic” refers to all of the following: hardware-only circuit implementations (such as implementations in only analog and/or digital circuitry); combinations of circuits and software (and/or firmware) such as (as applicable) to a combination of processor(s) or to portions of processor(s)/software (including digital signal processor(s)), software and memory(ies) that work together to cause an apparatus such as a mobile phone or server, to perform various functions; and circuits such as a microprocessor(s) or a portion of a microprocessor(s) that require software or firmware for operation even if the software or firmware is not physically present. This definition of “circuitry” or “logic” applies to all uses of this term in this application, including in any claims. As a further example, as used in this application, the term “circuitry” or “logic” also covers an implementation of merely a processor (or multiple processors) or portion of a processor and its (or their) accompanying software and/or firmware. The term “circuitry” or “logic” also covers, for example, and if applicable to a particular claim element, an integrated circuit for a memory device.

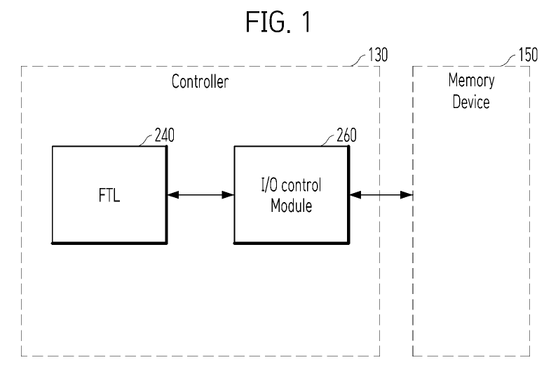

FIG. 1 illustrates a memory system.

Referring to FIG. 1, the memory system may include a memory device 150 and a controller 130. The memory device 150 and the controller 130 may be physically or functionally separated from each other. The memory device 150 and the controller 130 may communicate with each other.

The controller 130 may include a flash translation layer (FTL) 240 and an input/output (I/O) control module 260. The FTL 240 may perform a data processing operation for transferring host data from a host 102 to the memory device 150 in order to store the host data in the memory device 150. Because a logical address scheme identified by the host 102 and a physical address scheme identified within the memory system are different from each other, the FTL 240 may determine a location, in which the data is to be stored in the memory device 150. The FTL 240 may generate map data for associating a logical address with a physical address of the data. The logical address of the data may be determined and identified by the host 102 and the physical address of the data may be determined and identified by the memory system.

The I/O control module 260 may control the operation of storing, in the memory device 150, the data transferred from the FTL 240. The memory device 150 may include a plurality of planes, each including a plurality of nonvolatile memory cells. When the I/O control module 260 transmits a read command to the memory device 150, data may be read from the memory cells and output to the I/O control module 260.

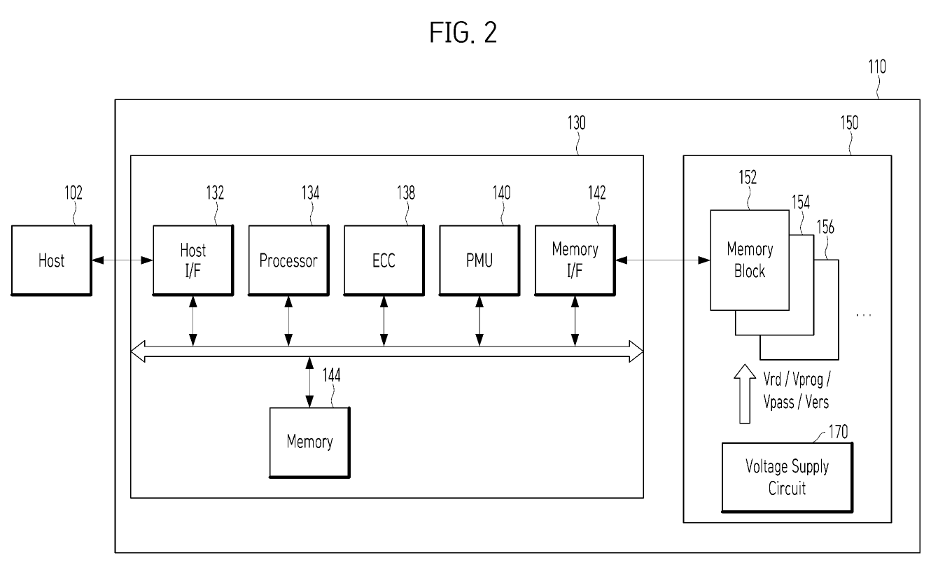

According to an embodiment, the I/O control module 260 may be included in a memory interface 142 shown in FIG. 2. According to an embodiment, the I/O control module 260 may be arranged between the FTL 240 and the memory interface 142.

The memory plane may include at least one memory block, a driving circuit configured to control an array including the nonvolatile memory cells, and at least one buffer configured to temporarily store data input to or output from the plurality of nonvolatile memory cells. The memory plane may be understood as a logical or physical partition.

The memory device 150 may include a plurality of memory blocks. A memory block may be understood as a group of nonvolatile memory cells, from which data is erased together through an erase operation. Each of the memory blocks may include a page as a group of nonvolatile memory cells, which store data together during a program operation and output data together during a read operation.

In an embodiment, the memory system may perform a foggy program operation and a fine program operation to program multi-bit data.

The memory system may perform a foggy-fine program operation to program multi-bit data. The foggy-fine program operation may be performed through plural program operations in which plural ISPP step pulses are applied successively to program multi-bit data in a nonvolatile memory cell until the nonvolatile memory cell connected to a specific word line is fully programmed with the multi-bit data. In the foggy-fine program operation, plural program pulses are alternatively applied to plural word lines to perform plural program operations regarding the multi-bit data. While a program operation is performed through a specific word line, another program operation may not be performed through another word line.

FIG. 2 illustrates a data processing system.

Referring to FIG. 2, the data processing system may include the host 102 coupled with the memory system 110. The memory device 150 and the controller 130 may be implemented with a single chip or a plurality of chips.

The memory device 150 may include a voltage supply circuit 170 configured to supply voltages for operations on the memory block. The memory device 150 may store information regarding various voltages to be supplied to the memory block depending on an operation. For example, when multi-bit data are stored in a nonvolatile memory cell in the memory block, plural levels of the read voltage Vrd may be required for reading the multi-bit data.

The host 102 may include a portable electronic device, e.g., a mobile phone, an MP3 player, a laptop computer, etc., or a non-portable electronic device, e.g., a desktop computer, a game player, a television, a projector, etc.

The controller 130 may control the memory device 150 in response to a request from the host 102. For example, the controller 130 may perform a read operation to provide the host 102 with data read from the memory device 150 and may perform a write or program operation to store, in the memory device 150, data provided from the host 102. In order to perform data I/O operations, the controller 130 may control and manage internal operations of reading data, programming data, erasing data, or the like.

Referring to FIG. 2, the controller 130 may include a host interface 132, a processor 134, an error correction code (ECC) circuitry 138, a power management unit (PMU) 140, a memory interface 142, and a memory 144.

For example, the memory system 110 may be implemented with any of various types according to a protocol of a host interface. Non-limiting examples of suitable memory system 110 may include a solid state drive (SSD), a multimedia card (MMC), an embedded MMC (eMMC), a reduced size MMC (RS-MMC), a micro-MMC, a secure digital (SD) card, a mini-SD, a micro-SD, a universal serial bus (USB) memory device, a universal flash storage (UFS) device, a compact flash (CF) card, a smart media (SM) card, a memory stick, and the like.

The host interface 132 may be suitable for transmitting a signal to and receiving a signal from the host 102. The host 102 and the memory system 110 may communicate with each other according to a predetermined communication standard or interface. Examples of the standard or interface may include Universal Serial Bus (USB), Multi-Media Card (MMC), Parallel Advanced Technology Attachment (PATA), Small Computer System Interface (SCSI), Enhanced Small Disk Interface (ESDI), Integrated Drive Electronics (IDE), Peripheral Component Interconnect Express (PCIe or PCI-e), Serial-attached SCSI (SAS), Serial Advanced Technology Attachment (SATA), Mobile Industry Processor Interface (MIPI), and the like. The host interface 132 may be implemented as a type of layer such as a host interface layer (HIL).

Referring to FIG. 2, the ECC circuitry 138 may correct error bits of data read from the memory device 150 and may include an encoder and a decoder. The encoder may perform an encoding operation on data to be programmed in the memory device 150 to generate encoded data into which a parity bit is added. The decoder may detect and correct error bits in the encoded data read from the memory device 150. For example, after performing a decoding operation on the data read from the memory device 150, the ECC circuitry 138 may determine whether the error correction decoding has succeeded or not, and outputs a success signal or a fail signal based on a result of the decoding operation. In order to correct the error bits of the encoded data generated during the ECC encoding process, the ECC circuitry 138 may use the parity bit included in the encoded data. When a number of error bits is a threshold or greater, the ECC circuitry 138 may not correct the error bits and instead may output the fail signal.

According to an embodiment, the ECC circuitry 138 may be suitable for an error correction operation based on a coded modulation such as a low density parity check (LDPC) code, a Bose-Chaudhuri-Hocquenghem (BCH) code, a turbo code, a Reed-Solomon (RS) code, a convolution code, a recursive systematic code (RSC), a trellis-coded modulation (TCM), a Block coded modulation (BCM),or the like.

The PMU 140 may control electrical power provided to the controller 130. The PMU 140 may generate a trigger signal to enable the memory system 110 to urgently back up a current state when the electrical power supplied to the memory system 110 is unstable. According to an embodiment, the PMU 140 may be suitable for saving electrical power for an emergency.

The memory interface 142 may serve as an interface for communication between the controller 130 and the memory device 150 for the controller 130 to control the memory device 150. The memory interface 142 may generate a control signal for the memory device 150 and may process data input to, or output from, the memory device 150 under the control of the processor 134.

For example, when the memory device 150 includes a NAND flash memory, the memory interface 142 may include a NAND flash controller (NFC). The memory interface 142 may be implemented as a type of layer such as a flash interface layer (FIL).

The memory 144 may serve as a working memory of the memory system 110 110 or the controller 130 by temporarily storing transactional data for operations performed in the memory system 110 and the controller 130. For example, the memory 144 may temporarily store data read from the memory device 150 before the read data is output to the host 102. In addition, the controller 130 may temporarily store, in the memory 144, write data provided from the host 102 before programming the write data in the memory device 150. When the controller 130 controls operations of the memory device 150, data transferred between the controller 130 and the memory device 150 may be temporarily stored in the memory 144.

The memory 144 may include one or more of a command queue, a program memory, a data memory, a write buffer/cache, a read buffer/cache, a data buffer/cache, a map buffer/cache, and so on. The controller 130 may allocate spaces in the memory 144 for a data I/O operation. For example, the write buffer established in the memory 144 may temporarily store write data as a target of a program operation.

The memory 144 may be implemented with a volatile memory. For example, the memory 144 may be implemented with a static random access memory (SRAM), a dynamic random access memory (DRAM), or both. Although FIG. 2 illustrates the memory 144 disposed within the controller 130, the memory 144 may be provided within or external to the controller 130. For instance, the memory 144 may be embodied by an external volatile memory having a memory interface transferring data and/or signals between the memory 144 and the controller 130.

The processor 134 may control the overall operations of the memory system 110. For example, the processor 134 may control a program operation or a read operation of the memory device 150. The processor 134 may execute firmware to control the program operation or the read operation in the memory system 110. Herein, the firmware may be the FTL 240. The processor 134 may be implemented with a microprocessor, a central processing unit (CPU), or the like.

The processor 134 may perform an operation in response to or without a request from the host 102. The controller 130 may perform foreground and background operations of reading, writing and erasing data in the memory device 150. The background operation may include garbage collection, wear leveling, bad block management (identifying and processing bad blocks), or the like.

Referring to FIG. 2, the memory device 150 may include a plurality of memory blocks 152 to 156. Each memory block may have a three-dimensional stack structure for a high integration. The plurality of memory blocks 152 to 156 may be any of single-level cell (SLC) memory blocks, multi-level cell (MLC) memory blocks, or the like, according to the number of bits that may be stored in one memory cell.

In an embodiment, the memory device 150 may be implemented with MLC memory blocks such as a double-level cell (DLC) memory block, a triple-level cell (TLC) memory block, a quadruple-level cell (QLC) memory block, and a combination thereof. The DLC memory block may include a plurality of pages implemented by memory cells, each memory cell suitable for storing 2-bit data. The TLC memory block may include a plurality of pages implemented by memory cells, each memory cell suitable for storing 3-bit data. The QLC memory block may include a plurality of pages implemented by memory cells, each memory cell suitable for storing 4-bit data. In another embodiment, the memory device 150 may be implemented with a block including a plurality of pages implemented by memory cells, each memory cell suitable for storing five or more bits of data.

The memory device 150 may be embodied as a nonvolatile memory such as a flash memory, for example, a NAND flash memory, a NOR flash memory, or the like. The memory device 150 may be implemented by at least one of a phase change random access memory (PCRAM), a ferroelectrics random access memory (FRAM), a transfer torque random access memory (STT-RAM), and a spin transfer torque magnetic random access memory (STT-MRAM), or the like.

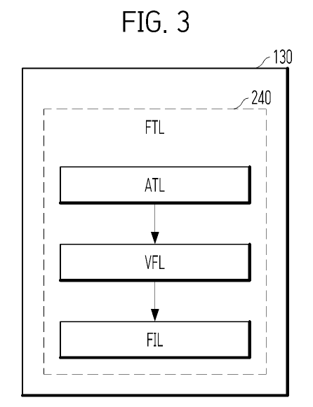

FIG. 3 illustrates the controller 130.

Referring to FIG. 3, the FTL 240 in the controller 130 may be divided into three layers: an address translation layer ATL, a virtual flash layer VFL and a flash Interface Layer FIL.

For example, the address translation layer ATL may convert a logical address LA transmitted from a file system into a logical page address. The address translation layer ATL may perform an address translation process regarding a logical address space. That is, the address translation layer ATL may perform an address translation process based on mapping information in which the logical page address LPA of the flash memory 140 is mapped to the logical address LA transmitted from the host. Such logical-to-logical address mapping information (hereinafter referred to as L2L mapping) may be stored in an area in which metadata is stored in the memory device 150.

The virtual flash layer VFL may convert the logical page address LPA, which is mapped by the address translation layer ATL, into a virtual page address VPA. Here, the virtual page address VPA may correspond to a physical address of a virtual memory device. That is, the virtual page address VPA may correspond to the memory block 60 in the memory device 150. If there is a bad block among the memory blocks 60 in the memory device 150, the bad block may be excluded by the virtual flash layer VFL. In addition, the virtual flash layer VFL may include a recovery algorithm for restoring the logical-to-virtual address mapping information (L2V mapping) stored in the memory device 150 and mapping information in the data region for storing user data. The recovery algorithm may be suitable for recovering the logical-to-virtual address mapping information (L2V mapping). The virtual flash layer VFL may perform an address conversion process regarding the virtual address space, based on the logical-to-virtual address mapping information (L2V mapping) restored through the recovery algorithm.

The flash interface layer FIL may convert a virtual page address of the virtual flash layer VFL into a physical page address of the memory device 150. The flash interface layer FIL performs a low-level operation for interfacing with the memory device 150. For example, the flash interface layer FIL may include a low-level driver for controlling hardware of the memory device 150, an error correction code (ECC) for checking and correcting an error in data transmitted from the memory device 150, and a module for performing operations such as a bad block management.

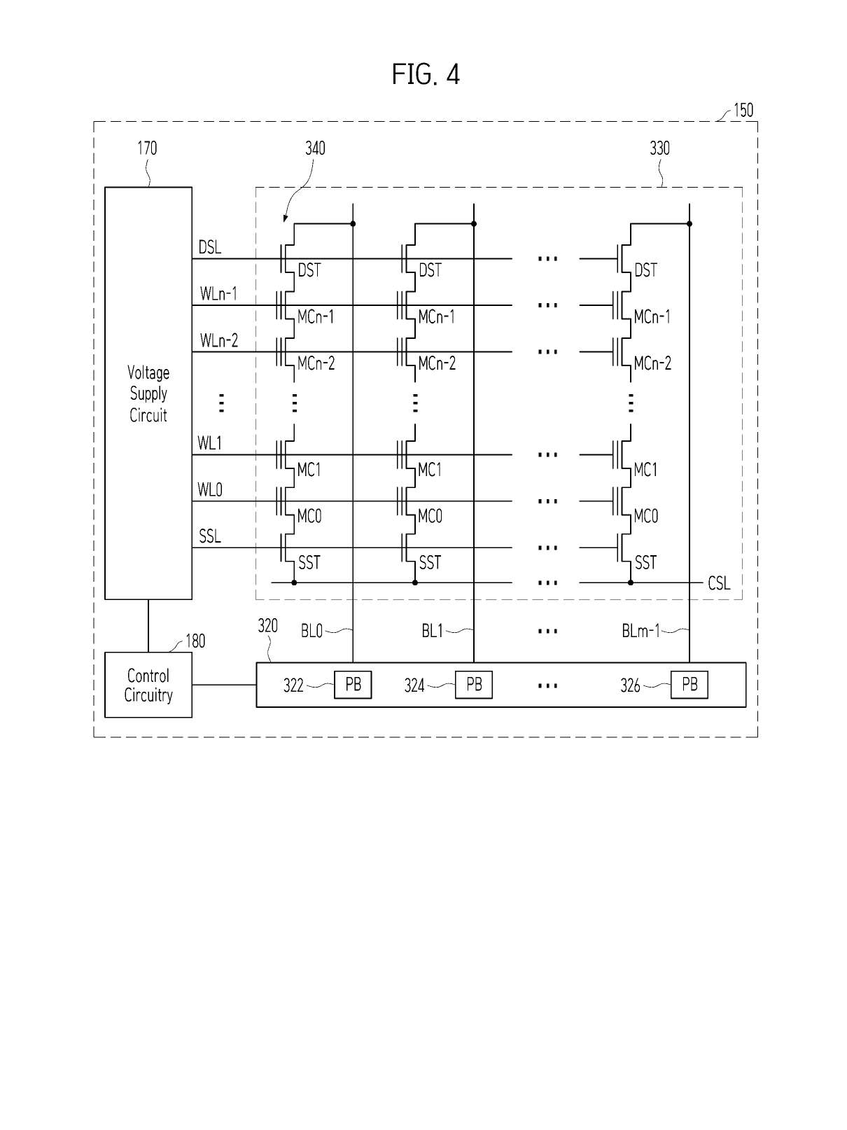

FIG. 4 illustrates the memory device 150.

Referring to FIG. 4, the memory device 150 may include at least one memory group 330 having a plurality of cell strings 340. Each cell string 340 may include a plurality of nonvolatile memory cells MC0 to MCn-1 connected to a respective bit line of a plurality of bit lines BL0 to BLm-1. The cell strings 340 may be disposed in respective columns of the memory group 330 and each cell string 340 may include at least one drain select transistor DST and at least one source select transistor SST. The nonvolatile memory cells MC0 to MCn-1 of each cell string 340 may be connected in series between a drain select transistor DST and a source select transistor SST. Each of the nonvolatile memory cells MC0 to MCn-1 may be configured as a multi-level cell (MLC) that stores data having plural bits per cell. The cell strings 340 may be electrically connected to the corresponding bit lines of the bit lines BL0 to BLm-1.

The memory group 330 may include NAND-type flash memory cells MC0 to MCn-1. In another embodiment, the memory group 330 may be implemented as a NOR-type flash memory, a hybrid flash memory in which at least two different types of memory cells are mixed or combined, or a one-chip NAND flash memory in which a controller is embedded in a single memory chip. In an embodiment, the memory group 330 may include a flash memory cell including a charge trap flash (CTF) layer that includes a conductive floating gate or insulating layer.

The memory group 330 in memory device 150 may include one or more memory blocks. According to an embodiment, the memory device 150 may have a two-dimensional (2D) or three-dimensional (3D) structure. For example, each of the memory blocks in the memory device 150 may be implemented as a 3D structure or a vertical structure. Each of the memory blocks may have a three-dimensional structure extending along first to third directions, for example, an x-axis direction, a y-axis direction, and a z-axis direction.

The memory group 330 including the plurality of memory blocks may be coupled to a plurality of bit lines BL, a plurality of string select lines SSL, and a plurality of drain select lines DSL, a plurality of word lines WL, a plurality of dummy word lines DWL, and a plurality of common source lines CSL. The memory group 330 may include a plurality of NAND strings NS corresponding to the respective cell strings 340. Each NAND string NS may include a plurality of memory cells MC and may be connected to a respective bit line of the bit lines BL. In addition, the string select transistor SST of each NAND string NS may be connected to a common source line CSL, and the drain select transistor DST of each NAND string NS may be connected to a corresponding bit line BL. In each NAND string NS, the memory cells MC may be arranged between the string select transistor SST and the drain select transistor DST.

The memory device 150 may include the voltage supply circuit 170 which may supply a word line voltage e.g., one or more predetermined voltages such as a program voltage, a read voltage, and a pass voltage, for respective word lines according to an operation mode, or may supply a voltage to a bulk (e.g., a well region) in which each memory block including the memory cells MC are formed. In this case, a voltage generating operation of the voltage supply circuit 170 may be performed under the control of control circuitry 180. Also, the voltage supply circuit 170 may generate a plurality of variable read voltages to distinguish a plurality of data from each other. The plurality of variable read voltages may be applied to nonvolatile memory cells in the memory group 330.

In response to the control of control circuitry 180, one of the memory blocks (or sectors) of the memory cell array may be selected, and one of the word lines of the selected memory block may be selected. Word line voltages may be supplied to the selected word line and the unselected word line, individually. The voltage supply circuit 170 may include a voltage generation circuit for generating target voltages having various levels.

In an embodiment, the voltage supply circuit 170 may be coupled to a first pin or pad receiving a first power voltage VCC applied from the outside (e.g., an external device) and a second pin or pad receiving the second power voltage VPP applied from the external device. The second power voltage VPP may have a greater voltage level, e.g., twice or higher than that of the first power voltage VCC. For example, the first power voltage VCC may have a voltage level of 2.0V to 5.5V, while the second power supply voltage may have a voltage level of 9V to 13V.

The voltage supply circuit 170 may include a voltage generation circuit for more rapidly generating the target voltages of various levels used in the memory group 330. The voltage generation circuit may use the second power supply voltage VPP to generate a target voltage, which may have a higher voltage level than the second power voltage VPP.

The memory device 150 may include a read/write circuit 320 controlled by the control circuitry 180. The read/write circuit 320 may operate as a sense amplifier or a write driver according to an operation mode. For example, in a verify operation and a read operation, the read/write circuit 320 may operate as a sense amplifier for reading the data from the memory cell array. In a program operation, the read/write circuit 320 may operate as a write driver that controls potentials of bit lines according to data to be stored in the memory cell array. The read/write circuit 320 may receive the data to be programmed to the cell array from page buffers during the program operation. The read/write circuit 320 may drive bit lines based on the input data. To this end, the read/write circuit 320 may include a plurality of page buffers (PB) 322 to 326 each corresponding to each column (or each bit line) or each column pair (or each bit line pair). According to an embodiment, a plurality of latches may be included in each of the page buffers.

According to an embodiment, the memory device 150 may receive a write command, write data and a physical address indicating a location, in which the write data are to be stored. The control circuitry 180 causes the voltage supply circuit 170 to generate a program pulse, a pass voltage, etc., used for a program operation performed in response to a write command, and to generate one or more voltages used for a verification operation performed after the program operation.

When a multi-bit data is programmed in the nonvolatile memory cells of the memory group 330, the error rate may be higher than that when a single-bit data is stored in the nonvolatile memory cells. For example, an error in the nonvolatile memory cells may be induced due to cell-to-cell interference (CCI). In order to reduce error in the nonvolatile memory cells, a width (deviation) of a threshold voltage distribution corresponding to stored data between the nonvolatile memory cells, should be reduced.

To this end, the memory device 150 may perform an incremental step pulse programming (ISPP) operation to effectively make a narrow threshold voltage distribution of the nonvolatile memory cells. In an embodiment, the memory device 150 may use the ISPP operation for the foggy-fine program operations.

By a foggy program operation disclosed below, formed is a threshold voltage distribution corresponding to a part of all states supposed to be formed. In this disclosure, the foggy program operation may be to form the threshold voltage distribution corresponding to a part of all states supposed to be formed. In this disclosure, a program operation may include the foggy program operation and a fine program operation. As an example, a foggy-fine program operation on TLCs is described below. However, the foggy-fine program operation may be applied to memory cells of various multiple bits per cell (BPC) such as QLCs.

As one of various embodiments of a program scheme, the foggy-fine program scheme may improve an interference phenomenon affecting an adjacent cell due to a program operation in a three-dimensional memory cell array. The foggy-fine program scheme may refer to a program scheme which includes a foggy program operation of programming selected memory cells to intermediate program states, and a fine program operation of programming the selected memory cells to target program states.

The foggy-fine program scheme may include operation S100 of performing a foggy program operation on selected memory cells using an intermediate verify voltage VRF_{IS} and operation S200 of performing a fine program operation on the selected memory cells using first to seventh verify voltages. The selected memory cells may belong to a physical page subject to the foggy-fine program operation. The selected memory cells may be coupled to a selected word line.

At operation S100, threshold voltages of the selected memory cells may change from an erase state E₀ to an erase state E_{IS} and the intermediate program state P_{IS}. The foggy program operation may temporarily change the threshold voltages of the selected memory cells to the erase state E_{IS} and the intermediate program state P_{IS} before changing, through the fine program operation, the threshold voltages of the selected memory cells to an erase state E and the target program states P1 to P7. The threshold voltages of the selected memory cells, which are supposed to belong to the intermediate program state P_{IS} by the foggy program operation, may be verified through the intermediate verify voltage VRF_{IS}.

At operation S200, the threshold voltages of the selected memory cells may change from the erase state E_{IS} and the intermediate program state P_{IS} to the erase state E and the target program states P1 to P7. Since the selected memory cells are TLCs, the threshold voltages of the memory cells may belong to one of the eight states, i.e., the erase state E and the target program states P1 to P7, after completion of the foggy-fine program operation. When each memory cell stores N bits, threshold voltages of the memory cells may belong to one of 2^{N} states, i.e., the erase state E and target program states P1 to P(2^{N}-1) after completion of a program operation.

For example, at operation S200, the threshold voltages of the selected memory cells of the erase state E_{IS} may be changed to the erase state E and the first to third target program states P1 to P3. When each of the selected memory cells stores N bits, the threshold voltages of the selected memory cells of the erase state E_{IS} may be changed to the erase state E and the first to (2^{N-1}-1)th target program states P1 to P(2^{N-1}-1), for example.

In addition, at operation S200, the threshold voltages of the selected memory cells of the intermediate program state P_{IS} may be changed to the fourth to seventh target program states P4 to P7. When each of the selected memory cell stores N bits, the threshold voltages of the selected memory cells of the intermediate program state P_{IS} may be changed to (2^{N-1})th to (2^{N}-1)th target program states P(2^{N-1}) to P(2^{N}-1), for example.

The threshold voltages of the selected memory cells, which are supposed to belong to the erase state E and the target program states P1 to P7 by the fine program operation, may be verified through the first to seventh verify voltages. For example, when each of the selected memory cell stores N bits, first to (2^{N-1})th verify voltages may verify the threshold voltages of the selected memory cells.

Operation S100 of performing the foggy program operation on the selected memory cells using the intermediate verify voltage VRF_{IS} may include operation S310 of applying a program inhibition voltage to bit lines coupled to the selected memory cells programmed to have the threshold voltages corresponding to the intermediate program state P_{IS} and the erase state E_{IS}; operation S330 of applying a program permission voltage to bit lines coupled to the selected memory cells not yet programmed to have the threshold voltages corresponding to the intermediate program state P_{IS}; operation S350 of applying a program voltage to a word line coupled to the selected memory cells; operation S370 of performing a verify operation on the selected memory cells using the intermediate verify voltage VRF_{IS}; and operation S390 of determining whether the selected memory cells are completely programmed to belong to the intermediate program state P_{IS}.

Each of the selected memory cells of the erase state E_{IS} may have a least significant bit (LSB) of 1. The selected memory cells to be programmed to the intermediate program state P_{IS} may have a least significant bit (LSB) of 0. The foggy program operation of operation S100 may be substantially a SLC program operation.

Operations S310 to S370 may be repeated until the selected memory cells are programmed to have the threshold voltages corresponding to the intermediate program state P_{IS}. The foggy program operation on the selected memory cells may include a plurality of program loops. Each of the program loops may include operations S310 to S370.

At operation S310, as a result of performing a verify operation in the previous program loop at operation S370, a program inhibition voltage may be applied to bit lines respectively coupled to the selected memory cells, which have been completely programmed to have the threshold voltages corresponding to the intermediate program state P_{IS} and the erase state E_{IS}. The threshold voltages of the program-completed memory cells of the intermediate program state P_{IS} and the erase state E_{IS} may be prevented from further programming. Thus, the program inhibition voltage may be applied to the bit lines respectively coupled to the program-completed memory cells so as not to increase the threshold voltages of the program-completed memory cells even when a program voltage is applied to a selected word line at operation S350.

At operation S330, a program permission voltage may be applied to bit lines coupled to the selected memory cells, which are not yet programmed to have the threshold voltages corresponding to the intermediate program state P_{IS} and the erase state E_{IS} as the result of performing the verify operation in the previous program loop at operation S370. In this manner, when the program voltage is applied to the selected word line at operation S350, the threshold voltages of the program-incomplete memory cells may increase.

At operation S350, a program voltage may be applied to a word line coupled to the selected memory cells. The threshold voltages of program-incomplete memory cells may increase whereas the threshold voltages of the program-inhibited memory cells may not. The program-incomplete memory cells may be the selected memory cells still having the threshold voltages lower than the intermediate verify voltage VRF_{IS}. The program-inhibited memory cells may be the selected memory cells already having the threshold voltages greater than the intermediate verify voltage VRF_{IS}. At the early stage of the foggy program operation, all memory cells may have threshold voltages corresponding to the erase state E₀. Therefore, all memory cells to be programmed to have the threshold voltages corresponding to the intermediate program state P_{IS} may be program-incomplete memory cells. As a program loop is repeated, the threshold voltages of the program-incomplete memory cells may gradually increase and the threshold voltages of some of the selected memory cells may become greater than the intermediate verify voltage VRF_{IS}. The selected memory cells, the threshold voltages of which become greater than the intermediate verify voltage VRF_{IS}, may become the program-inhibited cells. When the program loop continues to be repeated, the threshold voltages of the selected memory cells may eventually become greater than the intermediate verify voltage VRF_{IS}. As a result, all selected memory cells may be programmed to the intermediate program state P_{IS} and thus may be the program-inhibited cells.

The selected memory cells having the threshold voltages corresponding to the erase state E_{IS} may become the program-inhibited cells from the early stage of the foggy program operation.

At operation S370, a verify operation may be performed on the selected memory cells, through the intermediate verify voltage VRF_{IS}. The intermediate verify voltage VRF_{IS} may be applied to the selected word line. It may be determined whether the threshold voltages of the selected memory cells are greater than the intermediate verify voltage VRF_{IS}. The selected memory cells having threshold voltages greater than the intermediate verify voltage VRF_{IS} as a result of operation S370 may become the program-inhibited cells.

Operation S100 may end when the threshold voltages of all selected memory cells are determined as greater than the intermediate verify voltage VRF_{IS} at operation S390. When the threshold voltages of at least some of the selected memory cells are determined as lower than the intermediate verify voltage VRF_{IS} at operation S390, the process may proceed to operation S310 and a subsequent program loop may be repeated.

As the foggy program operation is performed as described above, a threshold voltage distribution corresponding to the initial erase state E₀ may be changed to the erase state E_{IS} and the intermediate program state P_{IS}. The memory cells of the erase state E_{IS} and the intermediate program state P_{IS} may be differentiated from each other according to the LSB of each memory cell. The foggy program operation may be substantially the same as a SLC program operation based on the LSB of each of the memory cells. The threshold voltage distribution of the memory cells after the completion of the foggy program operation may be divided into the erase state E_{IS} and the intermediate program state P_{IS}. Therefore, the LSB of each memory cell may be read using an intermediate read voltage R_{IS}.

Operation S200 of performing the fine program operation on the selected memory cells using the first to seventh verify voltages may include operation S315 of applying a program inhibition voltage to bit lines coupled to the selected memory cells programmed to have the threshold voltages corresponding to the target program states P1 to P7; operation S335 of applying a program permission voltage to bit lines coupled to the selected memory cells not yet programmed to have the threshold voltages corresponding to the target program states P1 to P7; operation S355 of applying a program voltage to a word line coupled to the selected memory cells; operation S375 of performing a verify operation on the selected memory cells using first to seventh verify voltages VRF1 to VRF7; and operation S395 of determining whether the selected memory cells are completely programmed to belong to the target program states P1 to P7.

Operations S315 to S375 may be repeated until the selected memory cells are programmed to have the threshold voltages corresponding to the target program states P1 to P7. The fine program operation of the selected memory cells may include a plurality of program loops. Each of the program loops may include operations S315 to S375.

At operation S315, as a result of performing a verify operation in the previous program loop at operation S375, a program inhibition voltage may be applied to bit lines respectively coupled to the selected memory cells, which have been completely programmed to have the threshold voltages corresponding to the target program states P1 to P7 and the erase state E. The threshold voltages of the program-completed memory cells of the target program states P1 to P7 and the erase state E may be prevented from further programming. Thus, the program inhibition voltage may be applied to the bit lines respectively coupled to the program-completed memory cells so as not to increase the threshold voltages of the program-completed memory cells even when a program voltage is applied to a selected word line at operation S355.

At operation S335, a program permission voltage may be applied to bit lines coupled to the selected memory cells, which are not yet programmed to have the threshold voltages corresponding to the target program states P1 to P7 and the erase state Eas the result of performing the verify operation in the previous program loop at operation S375. In this manner, when the program voltage is applied to the selected word line at operation S355, the threshold voltages of the program-incomplete memory cells may increase.

At operation S355, a program voltage may be applied to a word line coupled to the selected memory cells. The threshold voltages of program-incomplete memory cells may increase whereas the threshold voltages of the program-inhibited memory cells may not. The program-incomplete memory cells may be the selected memory cells still having the threshold voltages lower than the corresponding first to seventh verify voltages VRF1 to VRF7. The program-inhibited memory cells may be the selected memory cells already having the threshold voltages greater than the corresponding first to seventh verify voltages VRF1 to VRF7. At the early stage of the fine program operation, all memory cells may have threshold voltages corresponding to the erase state E_{IS} and the intermediate program state P_{IS}. Therefore, all memory cells to be programmed to have the threshold voltages corresponding to the respective target program states P1 to P7 may be program-incomplete memory cells. As a program loop is repeated, the threshold voltages of the program-incomplete memory cells may gradually increase and the threshold voltages of some of the selected memory cells may become greater than the corresponding first to seventh verify voltages VRF1 to VRF7. The selected memory cells, the threshold voltages of which become greater than the corresponding first to seventh verify voltages VRF1 to VRF7, may become the program-inhibited cells. When the program loop continues to be repeated, the threshold voltages of the selected memory cells may eventually become greater than the corresponding first to seventh verify voltages VRF1 to VRF7. As a result, all selected memory cells may be programmed to have the threshold voltages corresponding to the respective target program states P1 to P7 and thus may be the program-inhibited cells.

The selected memory cells having the threshold voltages corresponding to the erase state E may become the program-inhibited cells from the early stage of the foggy program operation.

At operation S375, a verify operation may be performed on the selected memory cells, through the corresponding first to seventh verify voltages VRF1 to VRF7. The first to seventh verify voltages VRF1 to VRF7 may be applied to the selected word line. It may be determined whether the threshold voltages of the selected memory cells are greater than the corresponding first to seventh verify voltages VRF1 to VRF7. The selected memory cells having threshold voltages greater than the corresponding first to seventh verify voltages VRF1 to VRF7 as a result of operation S375 may become the program-inhibited cells.

Operation S200 may end when the threshold voltages of all selected memory cells are determined as greater than the corresponding first to seventh verify voltages VRF1 to VRF7 at operation S395. When the threshold voltages of at least some of the selected memory cells are determined as lower than the corresponding first to seventh verify voltages VRF1 to VRF7 at operation S395, the process may proceed to operation S315 and a subsequent program loop may be repeated.

As the fine program operation is performed as described above, the threshold voltage distribution corresponding to the erase state E_{IS} and the intermediate program state P_{IS} may be changed to the erase state E and the first to seventh target program states P1 to P7. The threshold voltages of the memory cells corresponding to the erase state E_{IS} may be changed to the erase state E and the first to third target program states P1 to P3. The threshold voltages of the memory cells corresponding to the intermediate program state P_{IS} may be changed to the fourth to seventh target program states P4 to P7.

The memory cells corresponding to the erase state E and the first to seventh target program states P1 to P7 may be divided according to the values of MSB, CSB and LSB. For example, the memory cell having the threshold voltage corresponding to the erase state E may have the MSB of 0, the CSB of 1, and the LSB of 1. For example, the memory cell having the threshold voltage corresponding to the first target program state P1 may have the MSB of 0, the CSB of 0, and the LSB of 1.

For example, after completion of the foggy-fine program operation, the LSB of each of the selected memory cells may be read through a fourth read voltage R4. All memory cells having lower threshold voltages than the fourth read voltage R4 may have the LSB of 1 and all memory cells having higher threshold voltages than the fourth read voltage R4 may have the LSB of 0. Therefore, an LSB read operation may be performed on the memory cells through the fourth read voltage R4. The read voltage for the LSB read operation after the foggy program operation may be an intermediate read voltage R_{IS} and the read voltage for the LSB read operation after the fine program operation may be the fourth read voltage R4 greater than the intermediate read voltage R_{IS}.

In this disclosure, the group of voltage supply circuit 170, control circuitry 180 and read/write circuit 320 other than the memory group 330 within the memory device 150 may be referred to as a peripheral circuit.

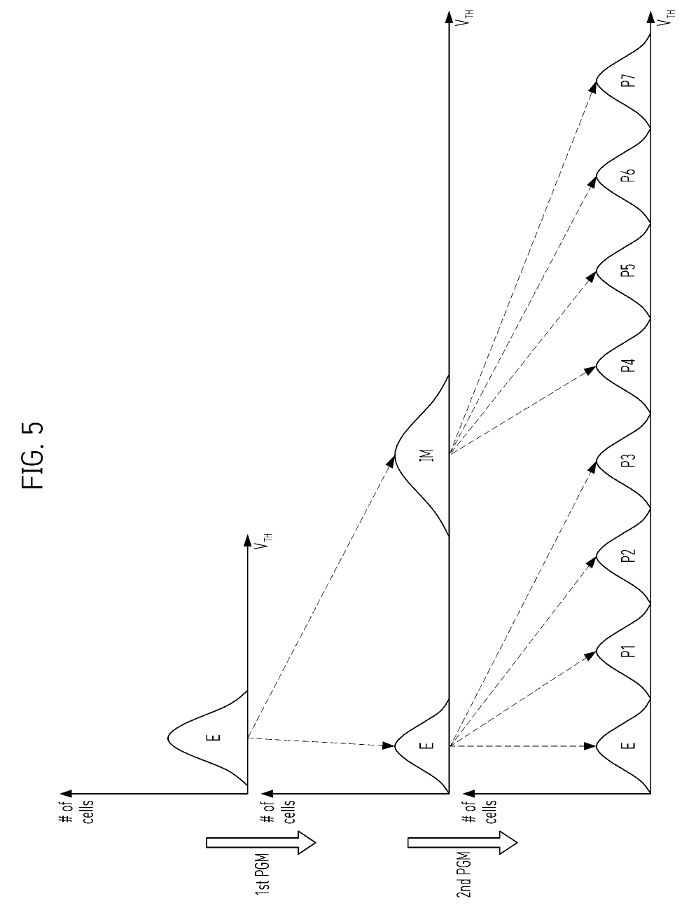

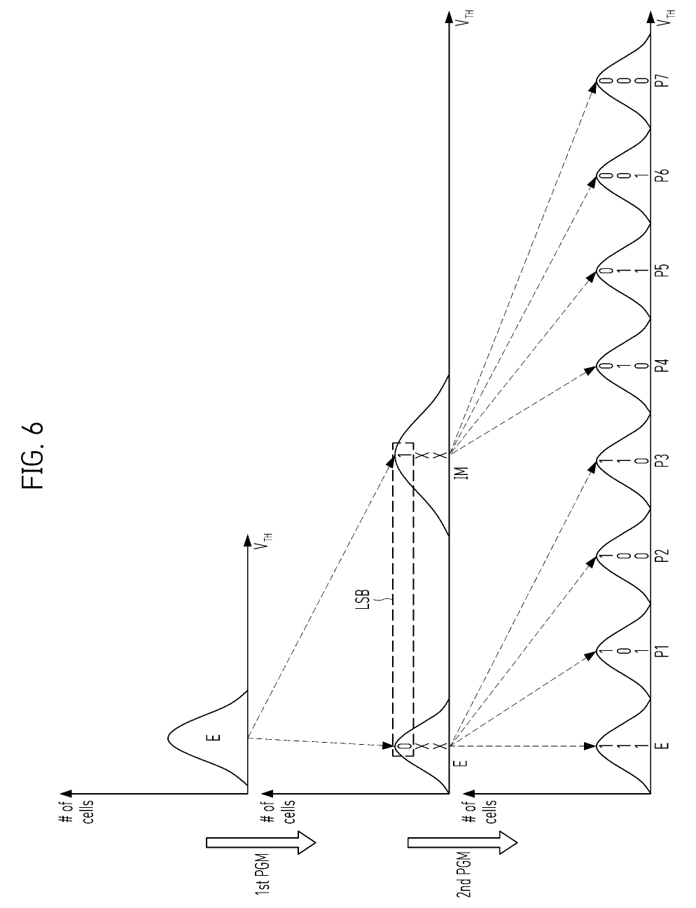

FIGS. 5 and 6 illustrate a program operation on TLCs according to an embodiment of the present disclosure.

In the case of a foggy-fine program scheme of FIGS. 5 and 6, the foggy program operation 1st PGM may be performed with only the LSB page data. The LSB page data of “0” and “1” may be distinguished according to a single read voltage.

Referring to FIGS. 5 and 6, the LSB page data of the memory cells having the threshold voltages corresponding to the erase state E and the first to third program states P1 to P3 may be “1” and the LSB page data of the memory cells having the threshold voltages corresponding to the fourth to seventh program state P4 to P7 may be “0”.

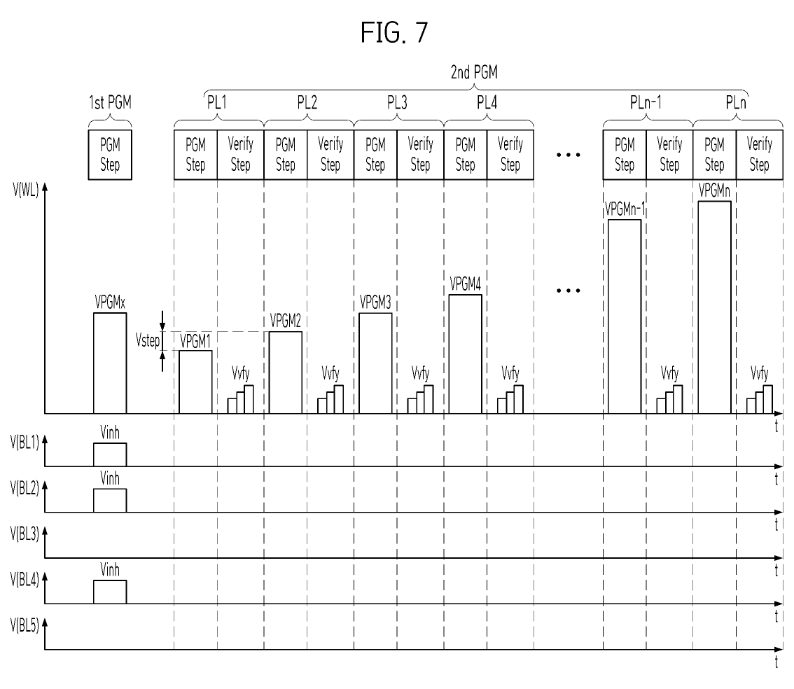

FIG. 7 illustrates voltages applied to a word line and bit lines during a foggy-fine program scheme on TLCs.

Referring to FIG. 7, the foggy program operation 1st PGM may be an operation of programming the memory cells to have the threshold voltages corresponding to one of the erase state and the intermediate state according to the data to be stored in each of the memory cells connected to the selected word line. The magnitude of the threshold voltage corresponding to the intermediate state may be larger than the magnitude of the threshold voltage corresponding to the erase state. The memory cells programmed to have the threshold voltages corresponding to the intermediate state during the foggy program operation 1st PGM may become to have the threshold voltages corresponding to one of the fourth to seventh program states during the fine program operation 2nd PGM. The memory cells programmed to have the threshold voltages corresponding to the erase state during the foggy program operation 1st PGM may become to have the threshold voltages corresponding to one of the erase state and the first to third program states during the fine program operation 2nd PGM.

Referring to FIG. 7, the target threshold voltages of the memory cells connected to the first, second and fourth bit lines BL1, BL2 and BL4 correspond to the third program state P3.

During the foggy program operation 1st PGM, a fixed program voltage VPGMx having a predetermined voltage level may be applied to the selected word line. Although FIG. 7 shows a case where the fixed program voltage VPGMx is applied once during the foggy program operation 1st PGM, the fixed program voltage VPGMx may be provided to the memory cells twice or more. The foggy program operation 1st PGM may include a plurality of program loops. In this case, even though the program loops proceed during the foggy program operation 1st PGM, the level of the program voltage applied to the word line does not increase and the program voltage may be the fixed program voltage having the fixed voltage level.

When the fixed program voltage VPGMx is applied to the word line, a program inhibition voltage Vinh may be applied to the bit lines BL1, BL2 and BL3 to which the memory cells having the erase state and the first to third program states as the target program states are connected. When the fixed program voltage VPGMx is applied to the word line, a program permission voltage may be applied to the bit lines BL3 and BL5 to which the memory cells having one of the fourth to seventh program states as the target program state are connected.

The foggy program operation 1st PGM may be performed through one application of the fixed program voltage VPGMx, performance of the verification step and application of an additional program voltage. The number of times the program voltage is applied and whether the verification step is performed during the foggy program operation 1st PGM are not limited.

The fine program operation 2nd PGM may include a plurality of program loops PL1 to PLn. One program loop includes a pulse application step PGM Step of applying a program voltage to a selected word line and a verification step of sensing whether a threshold voltage of each memory cell reaches a threshold voltage corresponding to a target program state. Each time the program loop proceeds, the level of the program voltage applied to the word line may increase by a step voltage Vstep compared to a program voltage in a previous program loop. Here, the step voltage may be a preset voltage value. This is called an incremental step pulse program (ISPP) scheme. Even though program loops corresponding to a preset maximum number of loops are performed, when all memory cells connected to the selected word line do not reach the target program state, it may be determined that the program operation is failed. The number of program states verified in each program loop may be at least two or more program states.

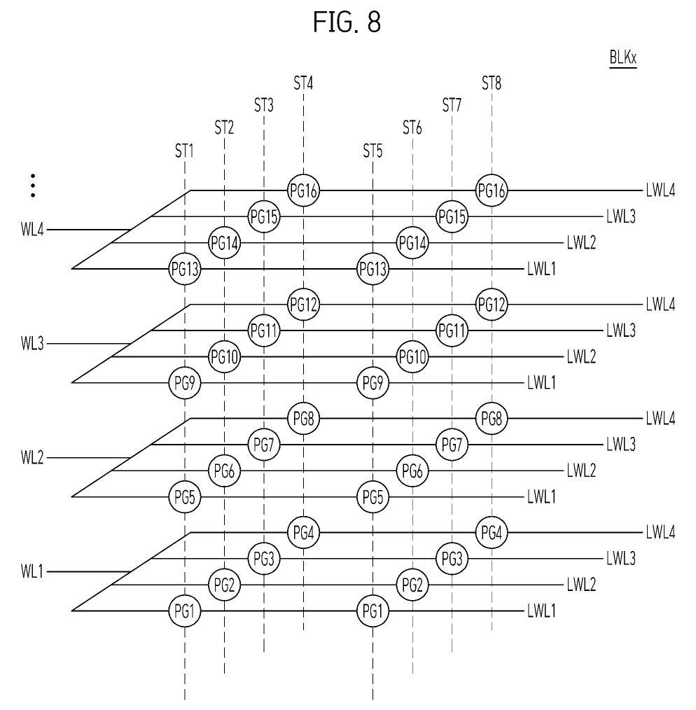

FIG. 8 schematically illustrates pages included in a memory block BLKx.

Referring to FIG. 8, the memory block BLKx may be connected to a plurality of physical word lines. One physical word line may be commonly connected to four logical word lines. Memory cells connected to one of the logical word lines may configure one logical page. For example, each of first to fourth physical word lines WL1 to WL4 may be commonly connected to first to fourth logical word lines LWL1 to LWL4.

For example, first to fourth strings ST1 to ST4 may be commonly connected to a bit line and fifth to eighth strings ST5 to ST8 may be commonly connected to another bit line.

For example, the number of logical word lines connected to one physical word line may be determined according to the number of strings commonly connected to one bit line. For example, when five strings are commonly connected to one bit line, one physical word line may be commonly connected to five local word lines. In this case, one physical word line may include five pages. Among the five pages, a programmed string and a not-yet-programmed string may be determined according to a string select signal (e.g., signals applied to the drain select line or the source select line).

The first logical word line LWL1 may be selected by the first string ST1 and the fifth string ST5. The second logical word line LWL2 may be selected by the second string ST2 and the sixth string ST6. The third logical word line LWL3 may be selected by the third string ST3 and the seventh string ST7. The fourth logical word line LWL4 may be selected by the fourth string ST4 and the eighth string ST8. One page may be selected by one logical word line and one physical word line.

That is, the first physical word line WL1 may include first to fourth pages PG1 to PG4. The second physical word line WL2 may include fifth to eighth pages PG5 to PG8. The third physical word line WL3 may include ninth to twelfth pages PG9 to PG12. The fourth physical word line WL4 may include thirteenth to sixteenth pages PG13 to PG16.

As discussed above, a foggy program operation may be to form the threshold voltage distribution corresponding to a part of all states supposed to be formed. A foggy-fine program scheme may include the foggy program operation and a fine program operation.

One of the features of the foggy-fine program scheme may be an internal read operation after the foggy program operation. The memory device 150 may not provide an external component with a result of the internal read operation and may internally utilize the result of the internal read operation.

Described is the foggy-fine program scheme on a physical page of QLCs, which can store therein data of 4 logical pages, i.e., LSB page data, lower-central significant bit (LCSB) page data, upper-central significant bit (UCSB) page data and MSB page data. Although the embodiments of the present disclosure are disclosed with reference to an example of the QLC, the embodiments are not be limited thereto. The embodiments may be applied to any kind of foggy program scheme having the feature of the internal read operation.

During the foggy program operation on the physical QLC page, 2 logical page-data sets or the LSB and LCSB page data may be programmed into the physical QLC page without caching the LSB and LCSB page data.

After completion of the foggy program operation, the memory system 110 may perform the internal read operation of internally reading the LSB and LCSB page data from the physical QLC page.

During the fine program operation on the physical QLC page, the memory system 110 may combine the LSB and LCSB page data with the UCSB and MSB page data to program the combined 4 logical page-data sets into the physical QLC page. Here, the LSB and LCSB page data have been internally read from the physical QLC page during the foggy program operation, and the UCSB and MSB page data are provided from the host 102 during the fine program operation.

In an embodiment, the foggy program operation may form the threshold voltage distribution corresponding to all states supposed to be formed.

Independent multi-plane operations may enable independent and concurrent operations per plane. Separate state machines for each plane may enable the application of different bias voltages for each plane to independently and concurrently service requests. It is described that the memory device 150 may include one or more memory dies, one of which includes six planes (plane 0, plane 1, plane 2 and plane 3). Although the embodiment describes four planes per memory die, a memory die may be divided into fewer or more than four planes.

All NAND array commands may be allowed independently on the plane level. An array command may cause an array operation such as programming data to the array, reading data from the array, erasing a block or other operations on the array. It is described that read commands (commands A and D) are sent to plane 0 and plane 3, a program command (command B) is sent to plane 1 and an erase command (command C) is sent to plane 2. Each plane can receive and service a different array command and the commands may be sent and completed at different times. Non-array commands (e.g., reset, timing mode changes, etc.) may be maintained as die-level commands.

Read operations may be allowed independently on the plane level. In an embodiment, four read operations A to D may be performed on the respective planes 0 to 3.

In an embodiment, groups of planes may allow one independent array operation amongst them. In this embodiment, array-operations may be performed on groups of planes independently. In an embodiment, planes may be grouped in pairs (e.g., each group includes two planes). In an embodiment, a group of planes may include more than two planes.

In the embodiments, the NAND commands may be split into two groups: 1) plane/group level commands and 2) die-level commands. The controller 130 and/or firmware may be aware of the distinction between plane-level and die-level commands and may handle the two types of commands differently. For example, a master queue and a slave queue per plane/group level may be implemented in the controller 130 and/or firmware to handle the die-level and plane-level commands.

The master queue and plane-level queues may be implemented in firmware, software, hardware, or a combination. An implementation with multiple queues may specify multiple queue identities. For example, a queue entry may include both a master queue ID and a slave queue ID to respectively indicate the master queue (e.g., the die-level queue) and slave queue (plane-level queue) that the command is routed to. Thus, commands issued by the controller 130 may have information to indicate that the command is a die level or a plane/group level. In an embodiment, all commands may first go to the master queue and the commands may be forwarded to the plane queues based on the target plane indicated in the command.

It is described that NAND commands are split into two groups: 1) plane or group level commands and 2) die level commands. The controller 130 may understand this command distinction and may handle the commands accordingly. For example, the controller 130 may have a slave queue per plane/group level and also a master queue on die level to handle these commands. In an embodiment, commands issued by the controller 130 may have information to indicate that the command is a die level or a group level. All commands may first go to the master queue and the controller 130 may forward the commands to the slave queue appropriately. When a command is a die level, the controller 130 may ensure all slave queues are empty before dispatching the command. The controller 130 may dispatch the die level command to one of the default slave queues but may also send a dummy/ghost command to other slave queues to prevent other slave queues from executing any plane level command during the execution of die level command. When a command is a plane level, the controller 130 may send the command to the slave queue. From there, the controller 130 may poll the memory device 150 to make sure that the plane is ready for a next command and then may issue another command to a memory die once it is ready.

Hereinafter, disclosed are flows of independent multi-plane operations. A first flow may be performed by the controller 130. A second flow may be performed by the memory device 150. The flows may be performed by hardware, software, firmware, or a combination of hardware (e.g., circuitry), software and firmware. For example, the first flow may be performed by a hardware controller, such as an ASIC NAND controller, a NAND-aware operating system or firmware or other control logic. The second flow may be performed by, for example, hardware or circuitry of the memory device 150.

The first flow may start with issuing a command to target a first plane of the memory device 150 at operation S401. For example, it is described that a host processor sends a request to the controller 130 to read data from, or program data to the memory device 150. The controller 130 may determine when the plane is ready to accept a command (e.g., by checking a ready signal by plane) and may send the array command to the target memory die. In an embodiment, the read or program command may indicate the target plane as part of the address section of the command. The memory die may then indicate that the target plane is busy while the target plane services the command. In an embodiment, the controller 130 may have other commands in its queues targeting other planes of the same memory die. While the plane is still busy due to servicing the first command, the controller 130 may issue a second command to target a second plane at operation S403. The controller 130 at operation S405 may then poll the status of the planes to determine when the commands have completed. For example, the controller 130 may issue a plane-level read status command to each plane, on which a command is being executed. In an embodiment, the memory die may include separate state machines for each plane, which may enable the memory die to accept and process the commands independently for each plane. In an embodiment, the memory die may need to accept a new command even if one of the plane/group is busy. Thus, commands may be sent to a plane independent of the status of other planes to enable independent and concurrent operation by the planes. The controller 130 can then track completion status at a plane-level.

The second flow may begin with receipt of a first command to target a first plane of the memory device 150 at operation S501. For example, a 3D NAND memory can receive from the controller 130 a command such as a read, program, erase, or other command. The command may target one of the multiple planes of the target memory die. The memory device 150 may start to service the first command at operation S503. For example, a 3D NAND memory may start to apply voltage pulses to target cells to program or read the data from the cells. Before completion of the first command, a second command targeting a second plane may be received at operation S505 while the first command is still being serviced. The memory device 150 at operation S507 may then start servicing the second command targeting the second plane independent of the status of the first plane. Thus, the commands may be different types of commands (e.g., one read targeting plane 0 and one write command targeting plane 1), may be for different modes (e.g., one SLC and one TLC) and may start and finish at different times for independent and concurrent operations.

During a program operation on the plurality of memory blocks 152 to 156 of multiple level cell memory blocks such as the DLC memory block, TLC memory block, QLC memory block and so forth, the memory cells are typically programmed into one of 2^{N} possible threshold voltages to store N bits of information. To read this data, a series of read operations at predetermined read levels (e.g., a subset of 2^{N}-1 read levels) are performed. The threshold voltage may be achieved by applying a series of pulse application steps with increasing magnitude to the control gate of target memory cell with each pulse application step followed by a series of verification steps to compare the threshold voltage of the target NAND cells against specific verify levels. A pulse application step and a number of verification steps following the pulse application step may be referred to as a program loop and a program operation may include a plurality of program loops, as discussed with reference to FIG. 7.

In an embodiment, the memory device 150 may incorporate the multi-plane architecture to enhance performance and throughput by enabling simultaneous execution of multiple program, read and erase operations.

The memory system may be designed to support the multi-plane program scheme for improved throughput where data is simultaneously programmed into pages of two or more planes. For example, the memory device 150 may support the six-plane architecture which allows the host 102 to program data into the pages of six different planes concurrently achieving 6x data programming in approximately a same unit time.

In the multi-plane architecture of memory device 150, plane-to-plane variation in the program-speed may arise due to the factors like the difference in the gate voltage, threshold voltage and program slope of memory cell and the distance from the voltage supplies & charge pumps to each plane and so forth.

As a result, the multi-plane program operation on each plane may progress at a different pace and some fast-to-program planes on which a program operation is performed fast, may complete the program operation for some program-target levels earlier than other slow-to-program planes on which a program operation is performed slowly. Eventually, the program operation for all program-target levels may be completed on the fast-to-program planes a few pulse application steps ahead the slow-to-program planes.

Even though the performance of multi-plane program operation may be limited by the slowest-to-program plane(s), of which the program operation is performed with the slowest speed, the bit line and word line operations for verification-pass planes, on which the verification step has passed, may be managed differently from verification-fail planes, on which the verification step has failed, to improve the power consumption that is one of the key factors to have an edge over the competition for applications like artificial intelligence, cloud computing and big-data.

According to an embodiment of the present disclosure, the power consumption during the multi-plane program operations may be improved by skipping the precharge of the bit lines in a plane during the verification steps on the plane for a program-target level in remaining program loops after an M^{th} program loop when the plane has passed the predictive-CSC-verification for the program-target level in the M^{th} program loop. The predictive-CSC-verification will be described later.

According to an embodiment of the present disclosure, the power-consumption during the multi-plane program operations may be improved further by skipping, when a plane among the selected planes passes the predictive-CSC-verification for a last program-target level in an L^{th} program loop among the plural program loops, the biasing of bit lines and word lines in the plane during the pulse application steps and verification steps on the plane for the last program-target level in remaining program loops after the L^{th} program loop among the plural program loops.

In order to reduce the number of verification steps in a program loop, a technique known as a predictive current sense comparison (CSC) scheme may be introduced. According to the predictive CSC scheme, a number of fail-bits from the information of previous program loops for a specific program-target level may be compared against some configurable CSC criteria under the current pulse application step, where a prediction is made such that when the number of fail-bits is less than the criteria then the given pulse application step is strong enough to have remaining memory cells passing the verification step for that specific program-target level. Accordingly, the voltage supply circuit 170 may stop providing a verify voltage for that specific program-target level and the voltage supply circuit 170 may program-inhibit those verification-pass cells in all future pulse application steps. One value proposition of such a predictive approach is to save one last verify voltage that occurs on every program-target level, which can cause a significant program performance (e.g., the program time amount, tPROG) improvement.

As discussed above, the predictive CSC scheme is a technology used to efficiently perform a verification step in a program loop within a program operation. While conventional methods involve verifying all cells for each pulse, the predictive CSC scheme predicts memory cells that are less likely to fail in the next verification step for a specific program-target level based on previous verification results for the specific program-target level and excludes the predicted memory cells from targets of the verification steps for the specific program-target level.

According to the predictive CSC scheme, analysed may be the results of verification steps performed for the specific program-target level. According to the predictive CSC scheme, checked may be the number of bits that failed at the previous verification step for the specific program-target level. According to the predictive CSC scheme, predicted may be the number of bits that are likely to fail at the current verification stage for the specific program-target level based on the checked number of fail-bits at the previous verification stage for the specific program-target level.

The predicted number of to-be-failed bits at the current verification stage for the specific program-target level may be compared with a predetermined CSC threshold. The CSC threshold may serve as a reference value to determine whether the program pulse at the current pulse application step is strong enough to program the remaining memory cells and therefore enough to have the remaining memory cells passing the current verification step for the specific program-target level.

When the predicted number of to-be-failed bits is less than the CSC threshold, the current verification step for the specific program-target level may not be performed, which means that the remaining memory cells are considered to be already programmed enough to pass the current verification step for the specific program-target level and are no longer subject to further verification.

In subsequent pulse application steps, the memory cells that have passed the verification step for the specific program-target level at the previous program loop may be program-inhibited, which prevents the memory cells from being affected by further pulse application steps.

The predictive CSC scheme improves the programming performance. The predictive CSC scheme reduces unnecessary verification steps, thereby increasing the programming speed. The predictive CSC scheme reduces the power consumption. The predictive CSC scheme decreases the power consumption by reducing the number of verification steps. The predictive CSC scheme extends the memory lifespan by reducing the stress applied to the memory cells.

An embodiment of the present disclosure may contribute to improving the efficiency of a multi-plane program operation and reducing the power consumption by utilizing the predictive CSC scheme.

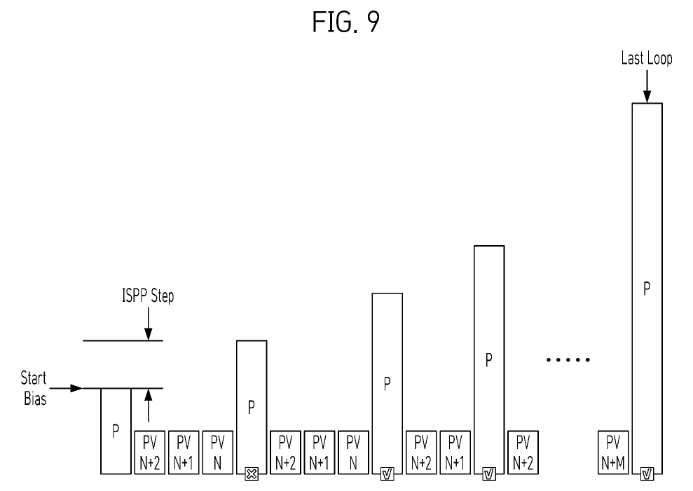

FIG. 9 schematically illustrates a program operation of the predictive CSC scheme according to an embodiment of the present disclosure.

In FIG. 9, the mark “P” represents a pulse application step and “PV N+m” represents a verification step for a program-target level “PV N+m”, m being an integer from zero (0) to M.

In FIG. 9, the mark “X” and “V” under the pulse application step represent the verification through the predictive CSC scheme (hereinafter, referred to as the predictive-CSC-verification), the predictive-CSC-verification being for the lowest program-target level at the previous verification step. The mark “X” represents that memory cells have failed the predictive-CSC-verification for the lowest program-target level at the previous verification step. The mark “V” represents that memory cells have passed the predictive-CSC-verification for the lowest program-target level at the previous verification step.

FIG. 9 shows a case where the memory cells as the targets of the 2^{nd} pulse application step have failed the predictive-CSC-verification for the N^{th} program-target level “PV N” or the lowest program-target level at the previous verification step.

However, the memory cells as the targets of the 3^{rd} pulse application step have passed the predictive-CSC-verification for the N^{th} program-target level “PV N” or the lowest program-target level at the previous verification step. Therefore, the verification step for the N^{th} program-target level “PV N” may not be performed from that point.

As discussed above for the multi-plane architecture of memory device 150, the multi-plane program operation on each plane may progress at a different pace and fast-to-program planes may complete the program operation for some program-target levels earlier than other slow-to-program planes. Therefore, there may be a case where the memory cells of fast-to-program planes pass the predictive-CSC-verification for a specific program-target level while the memory cells of slow-to-program planes still fail the predictive-CSC-verification for the specific program-target level.

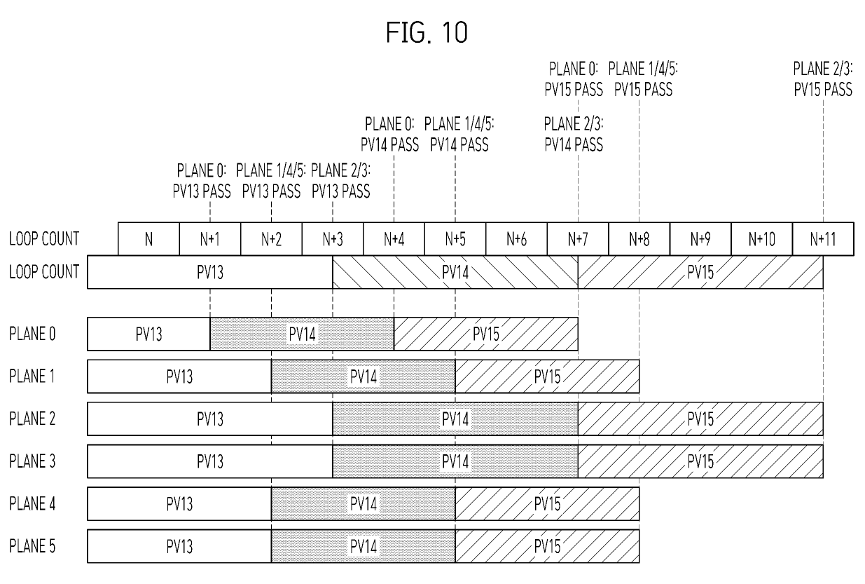

FIG. 10 illustrates multi-plane QLC program operations according to an embodiment of the present disclosure.

It is described that, among six planes or first to sixth planes Plane 0 to Plane 5 within the memory device 150, a first plane Plane 0 is faster than second, fifth and sixth planes Plane 1, Plane 4 and Plane 5, which are faster than third and fourth planes Plane 2 and Plane 3 with respect to their program speeds. The first plane Plane 0 may be referred to as the fastest-to-program plane and the third and fourth planes Plane 2 and Plane 3 may be referred to as the slowest-to-program planes.

Referring to FIG. 10, the fastest-to-program first plane Plane 0 passes the predictive-CSC-verification for the program-target level PV13 at the program loop#N+1, which is followed by the second, fifth and sixth planes Plane 1, Plane 4 and Plane 5 passing the predictive-CSC-verification for the program-target level PV13 at the program loop#N+2, which is followed by the slowest-to-program third and fourth planes Plane 2 and Plane 3 passing the predictive-CSC-verification for the program-target level PV13 at the program loop#N+3. The pass of the predictive-CSC-verification of the slowest-to-program third and fourth planes Plane 2 and Plane 3 causes the completion of the multi-plane program operations on the multi-planes Plane 0 to Plane 5 for the program-target level PV13.

Further, the fastest-to-program first plane Plane 0 passes the predictive-CSC-verification for the last program-target level PV15 at the program loop#N+7, which is followed by the second, fifth and sixth planes Plane 1, Plane 4 and Plane 5 passing the predictive-CSC-verification for the last program-target level PV15 at the program loop#N+8, which is followed by the slowest-to-program third and fourth planes Plane 2 and Plane 3 passing the predictive-CSC-verification for the last program-target level PV15 at the program loop#N+11. Accordingly, the multi-plane program operations on the multi-planes Plane 0 to Plane 5 for the program-target level PV15 is completed at the program loop#N+11 where all multi-planes Plane 0 to Plane 5 pass the predictive-CSC-verification for the program-target level PV15.

But due to the inconsistency in the program-speeds among the multi-planes Plane 0 to Plane 5, the multi-plane program operation is completed on the first plane Plane 0 prior to all other planes Plane 1 to Plane 5 in the program loop#N+7. The multi-plane program operations are completed on the second, fifth and sixth planes Plane 1, Plane 4 and Plane 5 prior to the third and fourth planes Plane 2 and Plane 3 in the program loop#N+8. Finally, the multi-plane program operations end when the multi-plane program operations are completed on the third and fourth planes Plane 2 and Plane 3 in the program loop#N+11.

The embodiments of the present disclosure recognize such inconsistency in the program-speeds among the different planes during the multi-plane program operations and dynamically manages the bit line and word line operations differently between the verification-pass planes and verification-fail planes for each program-target level to improve the overall power consumption.

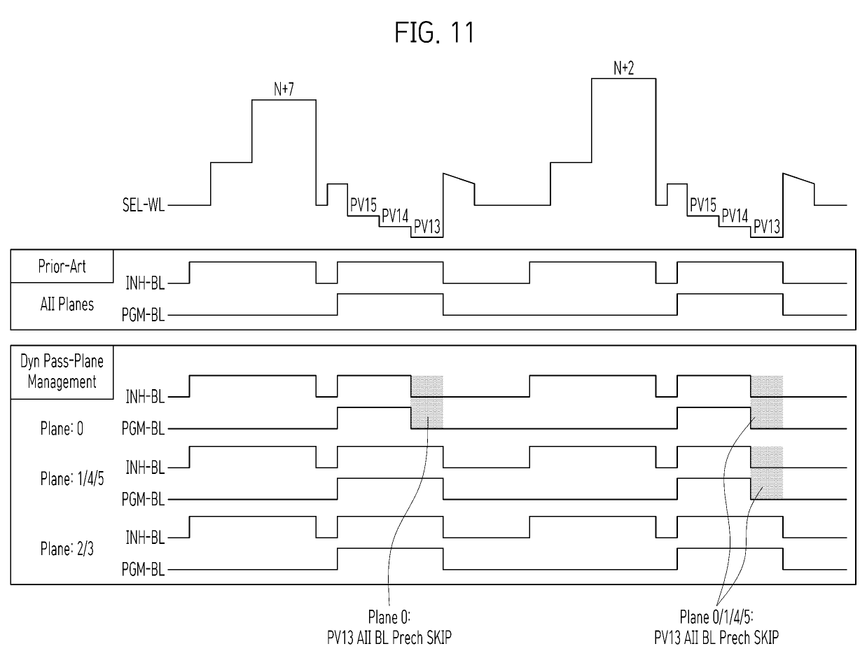

FIG. 11 illustrates the multi-plane program operations of programming pages of memory cells within the multi-planes Plane 0 to Plan 5 to the program-target level PV13 with respect to FIG. 10.

FIG. 11 shows a comparison between the prior-art and an embodiment of the present disclosure.

As shown in FIG. 10, the fastest-to-program first plane Plane 0 passes the predictive-CSC-verification for the program-target level PV13 in the program loop#N+1, which is followed by the second, fifth and sixth planes Plane 1, Plane 4 and Plane 5 passing the predictive-CSC-verification for the program-target level PV13 in the program loop#N+2, which is followed by the slowest-to-program third and fourth planes Plane 2 and Plane 3 passing the predictive-CSC-verification for the program-target level PV13 in the program loop#N+3.

According to the prior art of persisting in the precharge of the bit lines during the verification steps, even though the first plane Plane 0 has passed the predictive-CSC-verification for the program-target level PV13 in the program loop#N+1 and the second, fifth and sixth planes Plane 1, Plane 4 and Plane 5 in the program loop#N+2, all bit lines for the first to sixth planes Plane 0 to Plane 5 are precharged to perform the verification steps still in the program loop#N+1 and the program loop#N+2.

According to the prior art, when the selected word lines of the first to sixth planes Plane 0 to Plane 5 are biased to the program-target level PV13, the threshold voltages of all memory cells programmed below the program-target level PV13 change and the path from the bit line to the source line through the string opens, which results in the increased bit line current.

According to an embodiment of the present disclosure, skipped may be the precharge of the bit lines in a plane during the verification steps on the plane for the program-target level PV13 in remaining program loops after an M^{th} program loop when the plane has passed the predictive-CSC-verification for the program-target level PV13 in the M^{th} program loop, which minimizes the power overhead.

Referring to FIG. 11, according to an embodiment of the present disclosure, the precharge of the bit lines in the first plane Plane 0 may be skipped in remaining program loops after the program loop#N+1 and the precharge of the bit lines in each of the second, fifth and sixth planes Plane 1, Plane 4 and Plane 5 may be skipped in remaining program loops after the program loop#N+2 to improve the power consumption during the multi-plane program operations for the program-target level PV13.

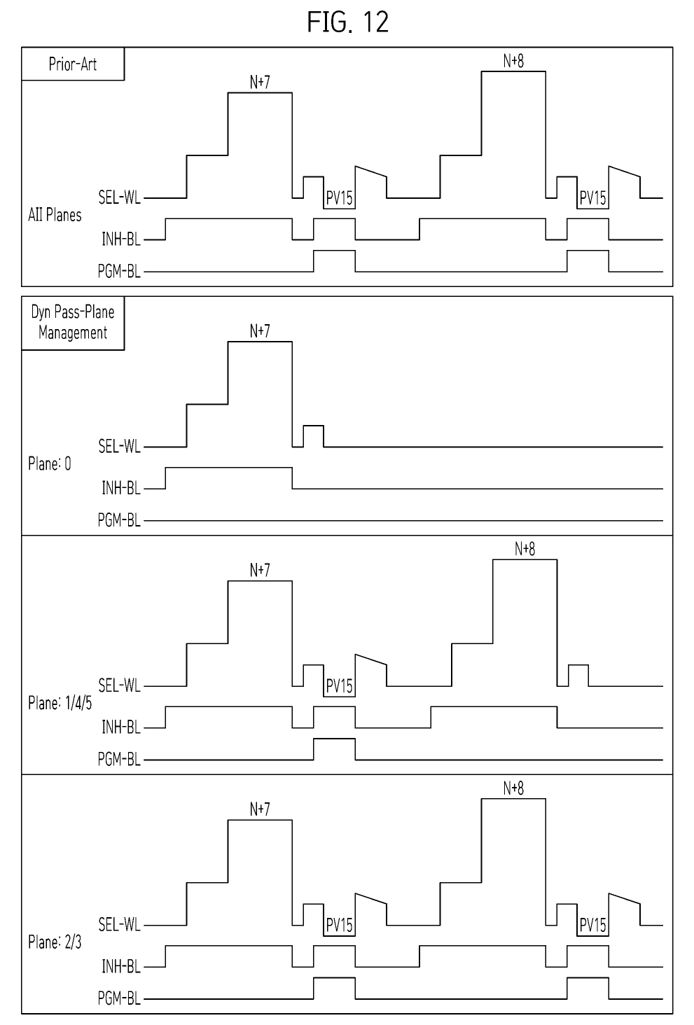

FIG. 12 illustrates the multi-plane program operations of programming pages of memory cells within the multi-planes Plane 0 to Plan 5 to the last program-target level PV15 with respect to FIG. 10.

FIG. 12 shows a comparison between the prior-art and an embodiment of the present disclosure.

As shown in FIG. 10, the fastest-to-program first plane Plane 0 passes the predictive-CSC-verification for the last program-target level PV15 at the program loop#N+7, which is followed by the second, fifth and sixth planes Plane 1, Plane 4 and Plane 5 passing the predictive-CSC-verification for the last program-target level PV15 at the program loop#N+8, which is followed by the slowest-to-program third and fourth planes Plane 2 and Plane 3 passing the predictive-CSC-verification for the last program-target level PV15 at the program loop#N+11.

According to the prior art of persisting in the biasing of bit line and global word line during the pulse application steps and verification steps, even though the first plane Plane 0 has passed the predictive-CSC-verification for the program-target level PV15 in the program loop#N+7 and the second, fifth and sixth planes Plane 1, Plane 4 and Plane 5 in the program loop#N+8, the biasing of bit line and global word line, which is the same for all of the first to sixth planes Plane 0 to Plane 5, are maintained for the pulse application steps and verification steps within remaining program loops.

According to the prior art, during the pulse application steps, the program-allowed bit lines are biased to 0V and the program-inhibited bit lines are biased to Vcore, and the selected word line is biased to Vpgm and the unselected word lines are biased to Vpass. Here, both the bit line operations and word line operations are major contributors to the power consumption.

According to an embodiment of the present disclosure, when a plane among the selected planes passes the predictive-CSC-verification for a last program-target level in an L^{th} program loop among the plural program loops, skipped may be the biasing of bit lines and word lines in the plane during the pulse application steps and verification steps on the plane for the last program-target level in remaining program loops after the L^{th} program loop among the plural program loops, which minimizes the power overhead.

Referring to FIG. 12, after the program loop#N+7, the biasing of both bit line and word line may be skipped for the first plane Plane 0, which has passed the predictive-CSC-verification for the last program-target level PV15 in the program loop#N+7 to improve the power consumption during the multi-plane program operation for the last program-target level PV15. After the program loop#N+8, the biasing of both bit line and word line is skipped for the second, fifth and sixth planes Plane 1, Plane 4 and Plane 5, which have passed the predictive-CSC-verification for the last program-target level PV15 in the program loop#N+8 to improve the power consumption during the multi-plane program operations for the last program-target level PV15.

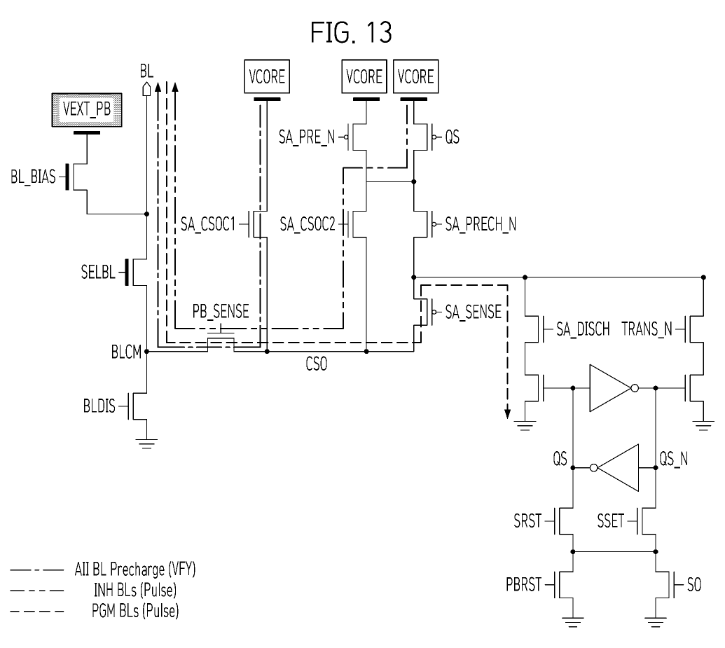

FIG. 13 illustrates a page buffer circuit configured to bias a bit line of the memory group 330 illustrated in FIG. 4.

One of the page buffers 322 to 326 illustrated in FIG. 4 may be implemented by the page buffer circuit illustrated in FIG. 13.

FIG. 13 shows current paths for bit line operations during the verification step and the pulse application step.

Referring to FIG. 13, the page buffer circuit may be connected to the bit line BL and configured to control the voltage level of the bit line BL during the multi-plane program operation.

The voltage level VCORE may represent the level of voltage supplied to the bit line BL. Various elements SA_PRE_N, SA_CSOC1, SA_CSOC2, SA_PRECH_N, SA_SENSE, SA_DISCH, TRANS_N, and so forth may be switches within the page buffer circuit. These switches may regulate the voltage level of the bit line BL and may execute the multi-plane program operation.

As a high-current bit line operation, the precharge of all bit lines through a first path initializes the bit line BL to the voltage level VCORE during the verification step. The precharge of all bit lines involves a high current flow of the first path, which results in significant power consumption.

As another high-current bit line operation, the precharge inhibition of a bit line through a second path charges the bit line BL to the voltage level VCORE during the pulse application step to inhibit the programming of corresponding memory cells. The precharge inhibition of a bit line also involves a high current flow of the second path and contributes to the power consumption.

As still another high-current bit line operation, the application of a program voltage to a bit line through a third path applies the program voltage to the memory cells through the bit line BL during the pulse application step.

According to an embodiment of the present disclosure, the above-discussed high-current bit line operations may be selectively skipped. For example, the precharge of all bit lines may be skipped for a plane, target memory cells of which have passed the verification step for a specific program-target level. For example, the precharge inhibition of a bit line may be skipped for a plane, target memory cells of which have passed the verification step for the last program-target level.

According to an embodiment of the present disclosure, reduced may be the power consumption and improved may be the efficiency of the multi-plane program operations.

According to an embodiment of the present disclosure, the high power consuming bit line and word line operations may be managed differently between the verification-pass planes and verification-fail planes for each program-target level, and therefore the power consumption for multiple program operations may be improved by skipping the precharge of the bit lines in a plane during the verification steps on the plane for a program-target level in remaining program loops after an M^{th} program loop when the plane has passed the predictive-CSC-verification for the program-target level in the M^{th} program loop.

According to an embodiment of the present disclosure, the power consumption for multiple program operations may be improved further by skipping, when a plane among the selected planes passes the predictive-CSC-verification for a last program-target level in an L^{th} program loop among the plural program loops, the biasing of bit lines and word lines in the plane during the pulse application steps and verification steps on the plane for the last program-target level in remaining program loops after the L^{th} program loop among the plural program loops.

The embodiments of the present disclosure may be extended to manage any plane-specific component such as controller, power supply, charge-pumps and so forth differently between the verification-pass planes and the verification-fail planes to improve the power consumption.

Although the foregoing embodiments have been illustrated and described in some detail for purposes of clarity and understanding, the present invention is not limited to the embodiments provided. There are many alternative ways of implementing the invention, as one skilled in the art will appreciate in light of the foregoing disclosure. The disclosed embodiments are thus illustrative, not restrictive. The present invention is intended to embrace all modifications and alternatives of the disclosed embodiments. Furthermore, the disclosed embodiments may be combined to form additional embodiments.

Indeed, implementations of the subject matter and the functional operations described in the present disclosure may be implemented in various systems, digital electronic circuitry, or in computer software, firmware, or hardware, including the structures disclosed in this specification and their structural equivalents, or in combinations of one or more of them. Embodiments of the subject matter described in this specification may be implemented as one or more computer program products, i.e., one or more modules of computer program instructions encoded on a tangible and non-transitory computer readable medium for execution by, or to control the operation of, data processing apparatus. The computer readable medium may be a machine-readable memory device, a machine-readable storage substrate, a memory device, a composition of matter affecting a machine-readable propagated signal, or a combination of one or more of them. The term “data processing unit” or “data processing apparatus” encompasses all apparatus, devices, and machines for processing data, including by way of example a programmable processor, a computer, or multiple processors or computers. The apparatus may include, in addition to hardware, code that creates an execution environment for the computer program in question, e.g., code that constitutes processor firmware, a protocol stack, a database management system, an operating system, or a combination of one or more of them.

A computer program (also known as a program, software, software application, script, or code) may be written in any form of programming language, including compiled or interpreted languages, and it may be deployed in any form, including as a stand-alone program or as a module, component, subroutine, or other unit suitable for use in a computing environment. A computer program does not necessarily correspond to a file in a file system. A program may be stored in a portion of a file that holds other programs or data (e.g., one or more scripts stored in a markup language document), in a single file dedicated to the program in question, or in multiple coordinated files (e.g., files that store one or more modules, sub programs, or portions of code). A computer program may be deployed to be executed on one computer or on multiple computers that are located at one site or distributed across multiple sites and interconnected by a communication network.

The processes and logic flows described in this specification may be performed by one or more programmable processors executing one or more computer programs to perform functions by operating on input data and generating output. The processes and logic flows may also be performed by, and an apparatus may also be implemented as, special purpose logic circuitry, e.g., an FPGA (field programmable gate array) or an ASIC (application specific integrated circuit).

Processors suitable for the execution of a computer program include, by way of example, both general and special purpose microprocessors, and one or more processors of any type of digital computer. Generally, a processor will receive instructions and data from a read only memory or a random-access memory or both. The essential elements of a computer are a processor for performing instructions and one or more memory devices for storing instructions and data. Generally, a computer will also include, or be operatively coupled to receive data from or transfer data to, or both, one or more mass memory devices for storing data, e.g., magnetic, magneto optical disks, or optical disks. However, a computer need not have such devices. Computer readable media suitable for storing computer program instructions and data include all forms of nonvolatile memory, media and memory devices, including by way of example semiconductor memory devices, e.g., EPROM, EEPROM, and flash memory devices. The processor and the memory may be supplemented by, or incorporated in, special purpose logic circuitry.

While the present disclosure contains many specifics, these should not be construed as limitations on the scope of any invention or of what may be claimed, but rather as descriptions of features that may be specific to particular embodiments of particular inventions. Certain features that are described in the present disclosure in the context of separate embodiments may also be implemented in combination in a single embodiment. Conversely, various features that are described in the context of a single embodiment may also be implemented in multiple embodiments separately or in any suitable sub-combination. Moreover, although features may be described above as acting in certain combinations, one or more features from a combination may in some cases be excised from the combination, and the combination may be directed to a sub-combination or a variation of a sub-combination.

Similarly, while operations are depicted in the drawings in a particular order, this should not be understood as requiring that such operations be performed in the particular order shown or in sequential order, or that all illustrated operations be performed, to achieve desirable results. Moreover, the separation of various system components in the embodiments described in the present disclosure should not be understood as requiring such separation in all embodiments.

Only a few embodiments and examples are described and other embodiments, enhancements and variations may be made based on what is described and illustrated in the present disclosure. Furthermore, the embodiments may be combined to form additional embodiments.

What is claimed is:

1. An operating method of a non-volatile memory device, having plural planes of memory cells each configured to store data of plural bits, the operating method comprising:
concurrently performing multiple program operations on planes selected from among the plural planes,
wherein each of the multiple program operations includes plural program loops each comprising a pulse application step and one or more verification steps including a predictive-CSC-verification according to a predictive current sense comparison (CSC) scheme, and
wherein the multiple program operations are performed while skipping, in response to a determination that a first plane among the selected planes passes the predictive-CSC-verification for a program-target level in an M^{th} program loop among the plural program loops, precharge of bit lines in the first plane during the verification steps on the first plane for the program-target level in remaining program loops after the M^{th} program loop, among the plural program loops.

2. The operating method of claim 1, wherein the multiple program operations are performed while skipping, in response to a determination that a second plane among the selected planes passes the predictive-CSC-verification for a last program-target level in an L^{th} program loop among the plural program loops, biasing of bit lines and word lines in the second plane during the pulse application steps and verification steps on the second plane for the last program-target level in remaining program loops after the L^{th} program loop, among the plural program loops.

3. The operating method of claim 1, wherein the predictive-CSC-verification is performed on a corresponding plane of the selected planes for a program-target level by:
determining that the corresponding plane passes the predictive-CSC-verification for the program-target level in response to a number of fail-bits for the program-target level, which is less than a threshold and acquired from information of previous program loops among the plural program loops; and
stopping subsequent verification steps on the corresponding plane for the program-target level while program-inhibiting the corresponding plane in the subsequent pulse application steps within the plural program loops.

4. An operating method of a non-volatile memory device, having plural planes of memory cells each configured to store data of plural bits, the operating method comprising:
concurrently performing multiple program operations on planes selected from among the plural planes,
wherein each of the multiple program operations includes plural program loops each comprising a pulse application step and one or more verification steps including a predictive-CSC-verification according to a predictive current sense comparison (CSC) scheme, and
wherein the multiple program operations are performed while skipping, in response to a determination that a first plane among the selected planes passes the predictive-CSC-verification for a last program-target level in an L^{th} program loop among the plural program loops, biasing of bit lines and word lines in the first plane during the pulse application steps and verification steps on the first plane for the last program-target level in remaining program loops after the L^{th} program loop, among the plural program loops.

5. The operating method of claim 4, wherein the multiple program operations are performed while skipping, in response to a determination that a second plane among the selected planes passes the predictive-CSC-verification for a program-target level in an M^{th} program loop among the plural program loops, precharge of bit lines in the first plane during the verification steps on the second plane for the program-target level in remaining program loops after the M^{th} program loop, among the plural program loops.

6. The operating method of claim 4, wherein the predictive-CSC-verification is performed on a corresponding plane of the selected planes for a program-target level by:
determining that the corresponding plane passes the predictive-CSC-verification for the program-target level in response to a number of fail-bits for the program-target level, which is less than a threshold and acquired from information of previous program loops among the plural program loops; and
stopping subsequent verification steps on the corresponding plane for the program-target level while program-inhibiting the corresponding plane in the subsequent pulse application steps within the plural program loops.

7. A non-volatile memory device comprising:
plural planes of memory cells each configured to store data of plural bits; and
a peripheral circuit configured to concurrently perform multiple program operations on planes selected from among the plural planes,
wherein each of the multiple program operations includes plural program loops each comprising a pulse application step and one or more verification steps including a predictive-CSC-verification according to a predictive current sense comparison (CSC) scheme, and
wherein the peripheral circuit is configured to concurrently perform the multiple program operations while skipping, when a first plane among the selected planes passes the predictive-CSC-verification for a program-target level in an M^{th} program loop among the plural program loops, precharge of bit lines in the first plane during the verification steps on the first plane for the program-target level in remaining program loops after the M^{th} program loop, among the plural program loops.

8. The non-volatile memory device of claim 7, wherein the peripheral circuit is configured to concurrently perform the multiple program operations while skipping, when a second plane among the selected planes passes the predictive-CSC-verification for a last program-target level in an L^{th} program loop among the plural program loops, biasing of bit lines and word lines in the second plane during the pulse application steps and verification steps on the second plane for the last program-target level in remaining program loops after the L^{th} program loop, among the plural program loops.

9. The non-volatile memory device of claim 7, wherein the peripheral circuit is configured to perform the predictive-CSC-verification on a corresponding plane of the selected planes for a program-target level by:
determining that the corresponding plane passes the predictive-CSC-verification for the program-target level when a number of fail-bits for the program-target level, which is acquired from information of previous program loops among the plural program loops, is less than a threshold; and
stopping subsequent verification steps on the corresponding plane for the program-target level while program-inhibiting the corresponding plane in the subsequent pulse application steps within the plural program loops.

10. A non-volatile memory device comprising:
plural planes of memory cells each configured to store data of plural bits; and
a peripheral circuit configured to concurrently perform multiple program operations on planes selected from among the plural planes,
wherein each of the multiple program operations includes plural program loops each comprising a pulse application step and one or more verification steps including a predictive-CSC-verification according to a predictive current sense comparison (CSC) scheme, and
wherein the peripheral circuit is configured to concurrently perform the multiple program operations while skipping, when a first plane among the selected planes passes the predictive-CSC-verification for a last program-target level in an L^{th} program loop among the plural program loops, biasing of bit lines and word lines in the first plane during the pulse application steps and verification steps on the first plane for the last program-target level in remaining program loops after the L^{th} program loop, among the plural program loops.

11. The non-volatile memory device of claim 10, wherein the peripheral circuit is configured to concurrently perform the multiple program operations further while skipping, when a second plane among the selected planes passes the predictive-CSC-verification for a program-target level in an M^{th} program loop among the plural program loops, precharge of bit lines in the first plane during the verification steps on the second plane for the program-target level in remaining program loops after the M^{th} program loop, among the plural program loops.

12. The non-volatile memory device of claim 10, wherein the peripheral circuit is configured to perform the predictive-CSC-verification on a corresponding plane of the selected planes for a program-target level by:
determining that the corresponding plane passes the predictive-CSC-verification for the program-target level when a number of fail-bits for the program-target level, which is acquired from information of previous program loops among the plural program loops, is less than a threshold; and
stopping subsequent verification steps on the corresponding plane for the program-target level while program-inhibiting the corresponding plane in the subsequent pulse application steps within the plural program loops.
